(19) United States
(12) Patent Application Publication
(10) Pub. No.: US 2011/0169991 A1
(43) Pub. Date: Jul. 14, 2011

(54) IMAGE SENSOR WITH EPITAXIALLY SELF-ALIGNED PHOTO SENSORS

(75) Inventors: Keh-Chiang Ku, Cupertino, CA (US); Chia-Ying Liu, Hsinchu City (TW); Hsin-Chih Tai, San Jose, CA (US); Vincent Venezia, Sunnyvale, CA (US); Yin Qian, Milpitas, CA (US); Duli Mao, Sunnyvale, CA (US)

(73) Assignee: OMNIVISION TECHNOLOGIES, INC., Santa Clara, CA (US)

(21) Appl. No.: 12/684,731

(22) Filed: Jan. 8, 2010

(51) Int. Cl. H04N 5/335; H04N 3/14; H01L 21/00

(52) U.S. Cl. 348/308; 438/57; 438/69; 348/E05.091; 257/E21.001

(57) ABSTRACT

An image sensor pixel includes a substrate doped to have a first conductivity type. A first epitaxial layer is disposed over the substrate and doped to also have the first conductivity type. A transfer transistor gate is formed on the first epitaxial layer. An epitaxially grown photo-sensor region is disposed in the first epitaxial layer and has a second conductivity type. The epitaxially grown photo-sensor region includes an extension region that extends under a portion of the transfer transistor gate.

### TECHNICAL FIELD

This disclosure relates generally to image sensors, and in particular but not exclusively, relates to CMOS image sensors.

### BACKGROUND INFORMATION

Image sensors are widely used in digital still cameras, cellular phones, security cameras, as well as in, medical, automobile, and other applications. Complementary metal-oxide-semiconductor (“CMOS”) technology is used to manufacture lower cost image sensors on silicon substrates. In a large number of image sensors, a photodiode structure called a pinned photodiode is used because of its low noise performance. In these conventional photodiode structures, a P+ type doped layer is ion implanted at or just below the silicon surface adjacent to a transfer gate. An N type doped layer is ion implanted deeper into the P type doped silicon substrate also adjacent to the transfer gate. The N type layer is the buried layer that stores charge away from the surface region where defects typically reside. The purpose of the P+ type doped layer is to passivate the defects on the photodiode surface. The relative location of the edges of the P+ type doped pinning layer, the N type doped photodiode region, and the adjacent transfer gate should be carefully engineered to improve photodiode charge transfer through the transfer gate. This becomes increasingly important as CMOS image sensors (“CIS”) continue to be miniaturized.

As CIS continue to miniaturize, the area of their pixels and principally their photodiode regions shrink, which results in less capacity to intercept light and hold photogenerated charge. Additionally, as backside illuminated (“BSI”) image sensors are introduced their thinned substrates put further constraints on photogenerated charge especially for longer wavelength light, which can pass through a silicon substrate without being fully absorbed. Although the advance of manufacturing technology facilitates the decrease in minimum allowable CMOS sizes, the reduction of variability of shape placement (i.e. alignment tolerance) has progressed at a slower rate. Image lag often depends on consistent alignment tolerances between the N type doped photodiode and its adjacent transfer gate edge.

### BRIEF DESCRIPTION OF THE DRAWINGS

Exemplary embodiments are described with reference to the following figures, wherein like reference numerals refer to like parts throughout the various views unless otherwise specified.

FIG. 1 (Prior Art) is a cross sectional view of a conventional front side illuminated CMOS image sensor pixel.

FIG. 2 is a cross sectional view of a structure that reduces overlap variability, reduces ion implanted related defects, and improves longer visible and infrared radiation absorption, in accordance with an embodiment.

FIG. 3A-3C are cross sectional views of a process for forming a photodiode and pixel, in accordance with an embodiment.

FIG. 4 is a block diagram illustrating a sensor, in accordance with an embodiment.

FIG. 5 is a circuit diagram illustrating sample pixel circuitry of two image sensor pixels within an image sensor array, in accordance with an embodiment.

FIG. 6 is a block diagram illustrating an imaging system, in accordance with an embodiment.

### DETAILED DESCRIPTION

Embodiments of a pixel, an image sensor, an imaging system, and methods of fabrication of a pixel, image sensor, and imaging system having improved image lag, noise, and long wavelength sensitivity characteristics are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects. For example, although not illustrated, it should be appreciated that image sensor pixels may include a number of material layers disposed on the front side or backside (e.g., pixel circuitry, dielectric layers, metal stacks, color filters, microlenses, etc.), as well as other conventional layers (e.g., antireflective films, etc.) used for fabricating CIS pixels. Furthermore, the illustrated cross sections of image sensor pixels illustrated herein do not necessarily illustrate the pixel circuitry associated with each pixel. However, it should be appreciated that each pixel may include pixel circuitry coupled to its collection region for performing a variety of functions, such as commencing image acquisition, resetting accumulated image charge, transferring out acquired image data, or otherwise.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

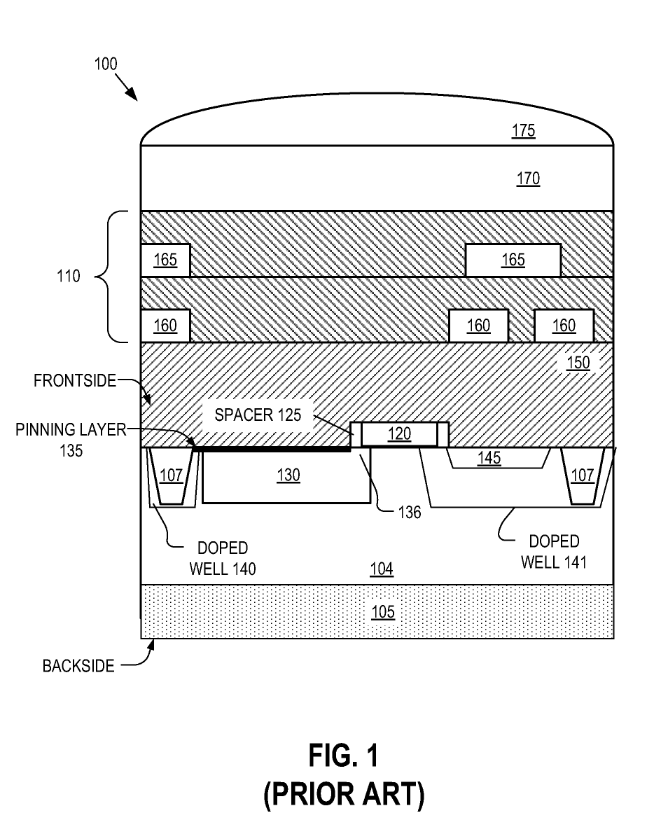

FIG. 1 illustrates a conventional CMOS image sensor (“CIS”) pixel 100. The front side of CIS pixel 100 is the side upon which pixel circuitry is formed within an epitaxial (“epi”) layer 104 which is disposed over a substrate 105 and is separated by shallow trench isolation regions (“STI”) 107 and over which a metal stack 110 for redistributing signals is formed. Pixel circuitry may also include a transfer gate 120 with spacers 125 on both sides. On one side of the transfer gate is formed a photodiode region (“PD”) 130, which extends underneath transfer gate 120. Pinning layer 135 is formed over PD region 130 and extends over doped well 140 in which STI 107 is contained. On the other side of transfer gate 130 is formed another doped well 141, which extends underneath transfer gate 120. Floating diode 145 is formed within doped well 141 adjacent to transfer gate 120. Dielectric layer 150 is formed over transfer gate 120, pinning layer 135, and floating diode 145.

For a front side illuminated image sensor the metal layers (e.g., metal layer 160 and 165) may be patterned in such a manner as to create an optical passage through which light incident on the front side of CIS pixel 100 can reach PD region 130. To implement a color CIS, the front side of CIS pixel 100 further includes a color filter layer 170 disposed under a microlens 175. Microlens 175 aids in focusing the light onto PD region 130. For a back side illuminated image sensor the light is incident on the backside and accordingly the color filter and microlens are positioned over the backside.

In operation, during an integration period (also referred to as an exposure or accumulation period), PD region 130 stores a level of charge proportional to the light intensity at its location in the array. After the integration period, transfer gate 120 is turned on to transfer the charge held in PD region 130 to floating diode 145. After the signal has been transferred to floating diffusion 145, transfer gate 120 is turned off again in preparation for a subsequent integration period. The signal on floating diffusion 145 may then be used to modulate an amplification or source follower transistor (not shown).

As illustrated in FIG. 1, a portion of PD region 130 extends under transfer gate 120 and spacer 125 to form region 136. Careful placement of PD region 130 under transfer gate 120 is beneficial for optimal transfer of signal from PD region 130 to floating diffusion 145. One common method is to insert the PD region dopant under the edge of transfer gate 120 through ion implantation of the dopant at an angle (e.g. 45 degrees) with respect to the surface normal. A number of sources of variability associated with this process require the overlap to be large in order to insure overlap and separation from the subsequent pinning layer 135. This large and variable overlap limits the amount of pixel miniaturization as well as contributes to variability of image lag performance. Additionally, the use of ion implantation introduces crystal defects that leads to dark current and contributes noise to the transferred signal. Furthermore the ion bombardment of the transfer gate can degrade the integrity of the underlying gate oxide. There is an upper limit on the ion implant parameters due to this onset of oxide degradation, which limits flexibility in design of PD region 130.

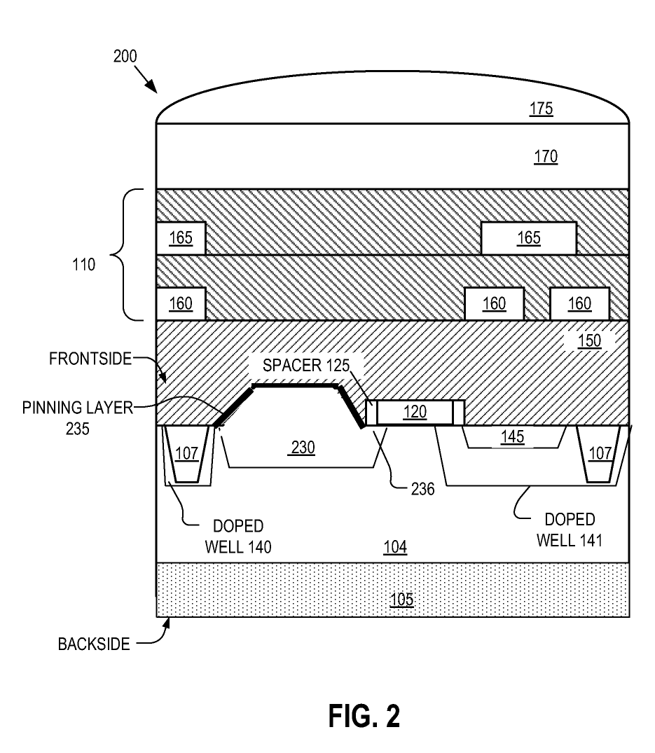

FIG. 2 is a side view of an epitaxially self-aligned photodiode pixel 200 according to an embodiment of the present application. The illustrated embodiment of pixel 200 includes some structures similar to those of pixel 100. Like structures have like labels. PD region 230 (also referred to generically as photo sensor region 230) is formed by first etching into epi layer 104 and then epitaxially growing a layer such as a Silicon Germanium (SiGe) layer or Silicon (Si) layer. The SiGe or Si epitaxial layer may be grown such that its upper surface extends up beyond the original surface of epi layer 104. A doped pinning layer 236 is formed along the upper surface of the SiGe or Si epitaxial layer. One improvement resulting from this structure is that extension region 236 of PD region 230 under transfer gate 120 and spacer 125 can be formed with less variability and can therefore be designed for smaller overlap without risk of failing to overlap. This enables more aggressive miniaturization to proceed. Also since ion implantation is not employed, surface defects and poly gate oxide integrity degradation usually associated with high energy implantation is avoided.

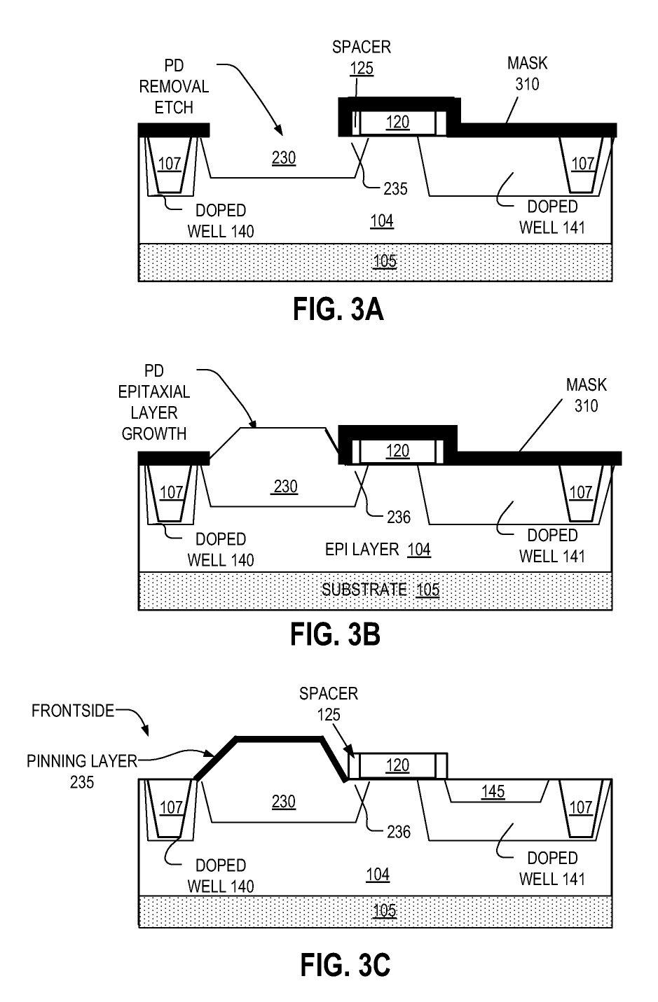

FIGS. 3A-3C illustrate one technique for fabricating epitaxially self-aligned photodiode 200, in accordance with one embodiment. FIG. 3A illustrates a cross section of a pixel similar to pixel 200 which has been fabricated to the point where transfer gate 120, spacers 125, STIs 107, and wells 140 and 141 are protected by etch mask 310 and PD region 230 has been removed from epi layer 104 by a PD removal etch to form a recess within epi layer 104. The PD removal etch process also creates extension region 236 under transfer gate 120 and is self aligned to transfer gate 120 and spacer 125. Extension region 236 may be between approximately 40 nm to approximately 400 nm wide. The PD removal etch process elements are similar to those used in strain engineered CMOS transistor technology and it is capable of providing a well controlled and repeatable extension region 236 under transfer gate 120 and spacer 125. The PD removal etch may be isotropic or anisotropic and it may use a gas or liquid etchant. An etchant that stops on the (111) crystallographic plane of Silicon is commonly used in advanced CMOS fabrication processes and may be applicable to this embodiment. The PD removal etch may employ a deep anisotropic etch step to create a deep cavity followed by a separate step designed to create extension region 236 under transfer gate 120 that is self aligned to transfer gate 120 and spacer 125.

Following the PD removal etch, as show in FIG. 3B, an epitaxially grown region, such as silicon or a silicon germanium alloy, is formed in the cavity formed by the PD removal etch. The epitaxially grown region selectively fills in extension region 236 under transfer gate 120 and spacer 125. The growing layer does not deposit on mask 310. During deposition of epitaxially grown PD region 230, an etchant species may be alternatively introduced between growth steps in order to remove any growth from over mask 310. In one embodiment, the epitaxially grown PD region 230 continues to grow above the original surface of epi layer 104. In this manner the thickness of PD region 230 can be increased and further add to its ability to better absorb longer wavelength photons which can penetrate further into SiGe and Si than shorter wavelength photons. In one embodiment, the epitaxially grown PD region 230 may form a hemispheroidal shape above the original or top surface of epi layer 104, which may serve as an optical lens for a frontside illuminated image sensor pixel to focus light into PD region 230 or an optical reflector for a backside illuminated image sensor pixel to reflect light that has passed through PD region 230 back into PD region 230. In one embodiment the epitaxially grown PD region 230 is between approximately 200 nm and approximately 2000 nm thick. In some embodiments, PD region 230 extends above the top of transfer gate 120, as illustrated.

In one embodiment, a Silicon Germanium alloy may be used for fabricating PD region 230. Silicon Germanium is effective in absorbing near infrared photons. The energy band gap of silicon is reduced as it is alloyed with increasing amounts of germanium, substantially increasing the absorption coefficients, especially at longer wavelengths. By using a Silicon Germanium alloy the absorption coefficients in the visible spectrum are also increased. The Silicon Germanium alloy may be doped as it is being grown by the addition of well known dopant sources for P or N type dopants during the growth process. The doping profile, i.e. its concentration as a function of growth thickness, may be controlled and varied.

Following formation of the self-aligned epitaxial grown PD region 230, pinning layer 235 is formed over the surface of PD region 230, as shown in FIG. 3C. The surface of PD region 230 may be ion implanted with for example a P type dopant using for example B₁₁, BF₂ or indium ions. For example, the P type dopant ion implant dose may be between 4×10¹² ions/cm² to 1×10¹⁵ ions/cm². If BF₂ is used, the ion implant energy may be between 5 and 500 KeV. Alternately pinning layer 235 may be formed during the epitaxial growth process for PD region 230 as a final step in which the dopants are added to the growing layer.

It can be appreciated by those of ordinary skill of the art that other methods may be utilized for forming an epitaxy photodiode. Thus, the present application contemplates and is meant to encompass all methods of forming such an epitaxy diode. Embodiments of epitaxially self-aligned photodiode pixel 200 provide significant benefits over past implementations. Firstly, the required overlap of PD region 230 and transfer gate 120 (e.g., extension region 236) is formed in a repeatable and compact way which allows further miniaturization of image sensor pixels. Secondly, the overlap is formed without the use of angled ion implants which may leave residual defects causing increased dark current and degrade transfer poly gate oxide integrity. Thirdly, the epitaxially grown PD region 230 may be formed with a silicon germanium alloy which has increased photon absorption properties and may extend the image sensor range further into the infrared spectrum while increasing absorption in the visible spectrum. Fourthly, the epitaxially grown PD region may be formed to extend above the original substrate surface to provide a thicker PD region to further enhance the absorption of longer wavelength radiation.

In the disclosed embodiment, substrate 105 may be P type doped, epi layer 104 may be P type doped, doped wells 140 and 141 may be P type doped, floating diffusion 145 may be N type doped, PD region 230 may be N type doped, pinning layer 235 may be P type doped, and transfer gate 120 may be N type doped. It should be appreciated that the conductivity types of all the elements can be swapped such that, for example, substrate 105 may be N+ doped, epi layer 104 may be N− doped, well regions 140 and 141 may be N doped, and PD region 230 may be P doped.

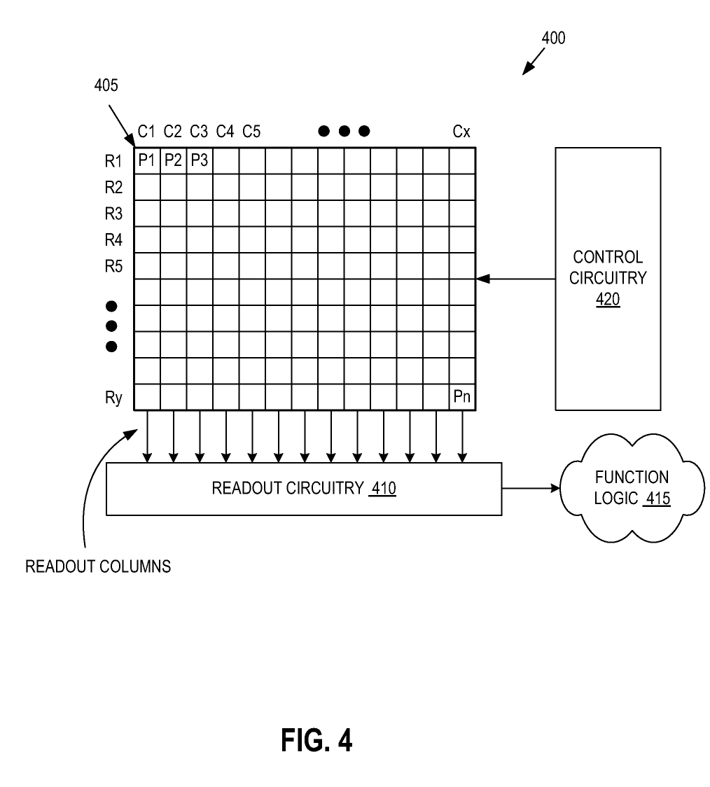

FIG. 4 is a block diagram illustrating a CIS 400, in accordance with an embodiment. The illustrated embodiment of CIS 400 includes pixel array 405 having some or all of the above described improved characteristics, readout circuitry 410, function logic 415, and control circuitry 420. Pixel array 405 is a two-dimensional (“2D”) array of image sensor pixels (e.g., pixels P1, P2 . . . , Pn). In one embodiment, each pixel is implemented using pixel 200, illustrated in FIG. 2. In one embodiment, each pixel is a CIS pixel. In one embodiment, pixel array 405 includes a color filter array including a color pattern (e.g., Bayer pattern or mosaic) of red, green, and blue filters. As illustrated, each pixel is arranged into a row (e.g., rows R1 to Ry) and a column (e.g., column C1 to Cx) to acquire image data of a person, place, or object, which can then be used to render a 2D image of the person, place, or object.

After each pixel has acquired its image data or image charge, the image data is readout by readout circuitry 410 and transferred to function logic 415. Readout circuitry 410 may include amplification circuitry, analog-to-digital (“ADC”) conversion circuitry, or otherwise. Function logic 415 may simply store the image data or even manipulate the image data by applying post image effects (e.g., crop, rotate, remove red eye, adjust brightness, adjust contrast, or otherwise). In one embodiment, readout circuitry 410 may readout a row of image data at a time along readout column lines (illustrated) or may readout the image data using a variety of other techniques (not illustrated), such as a column/row readout, a serial readout, or a full parallel readout of all pixels simultaneously. Control circuitry 420 is connected with pixel array 405 to control operational characteristic of pixel array 405. For example, control circuitry 420 may generate a shutter signal for controlling image acquisition.

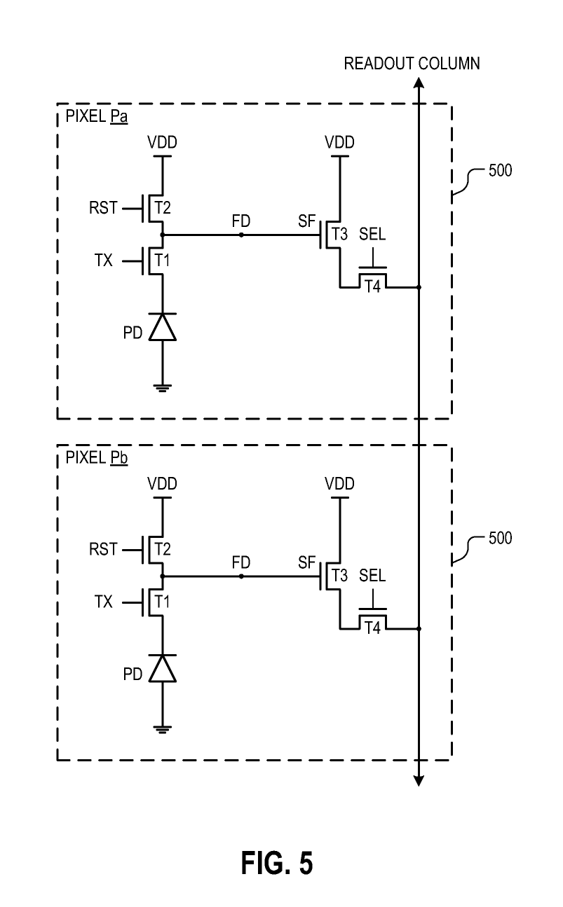

FIG. 5 is a circuit diagram illustrating a pixel circuitry 500 of two four-transistor (“4T”) pixels within a pixel array, in accordance with an embodiment of the invention. Pixel circuitry 500 is one possible pixel circuitry architecture for implementing each pixel within pixel array 405 of FIG. 4. However, it should be appreciated that embodiments of the present invention are not limited to 4T pixel architectures; rather, one of ordinary skill in the art having the benefit of the instant disclosure will understand that the present teachings are also applicable to 3T designs, 5T designs, and various other pixel architectures.

In FIG. 5, pixels Pa and Pb are arranged in two rows and one column. The illustrated embodiment of each pixel circuitry 500 includes a photodiode PD, a transfer transistor T1, a reset transistor T2, a source-follower (“SF”) transistor T3, and a select transistor T4. During operation, transfer transistor T1 receives a transfer signal TX, which transfers the charge accumulated in photodiode PD to a floating diffusion node FD. In one embodiment, floating diffusion node FD may be coupled to a storage capacitor for temporarily storing image charges.

Reset transistor T2 is coupled between a power rail VDD and the floating diffusion node FD to reset the pixel (e.g., discharge or charge the FD and the PD to a preset voltage) under control of a reset signal RST. The floating diffusion node FD is coupled to control the gate of SF transistor T3. SF transistor T3 is coupled between the power rail VDD and select transistor T4. SF transistor T3 operates as a source-follower providing a high impedance connection to the floating diffusion FD. Finally, select transistor T4 selectively couples the output of pixel circuitry 500 to the readout column line under control of a select signal SEL.

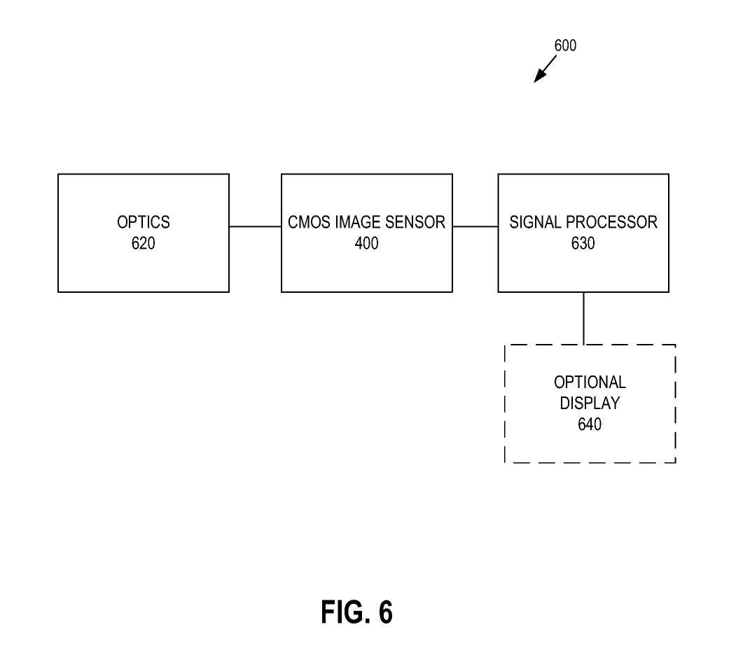

FIG. 6 illustrates an imaging system 600 that utilizes CIS 400, according to an embodiment of the disclosure. Image system 600 further includes imaging optics 620 for directing light from an item to be imaged onto CIS 400, and may also include a signal processor 630 for producing processed image data for display on a display 640.

The above description of illustrated embodiments of the invention, including what is described in the Abstract, is not intended to be exhaustive or to limit the embodiments to the precise forms disclosed. While specific embodiments are described herein for illustrative purposes, various modifications are possible within the scope, as those skilled in the relevant art will recognize. These modifications can be made in light of the above detailed description. Examples of some such modifications include dopant concentration, layer thicknesses, and the like. Further, although the embodiments illustrated herein refer to CMOS sensors using frontside illumination, it will be appreciated that they may also be applicable to CMOS sensors using backside illumination.

The terms used in the following claims should not be construed to limit the invention to the specific embodiments disclosed in the specification. Rather, the scope is to be determined entirely by the following claims, which are to be construed in accordance with established doctrines of claim interpretation.

What is claimed is:

1. An image sensor pixel, comprising:
a substrate doped to have a first conductivity type;
a first epitaxial layer disposed over the substrate and doped to have the first conductivity type;
a transfer transistor gate disposed over the first epitaxial layer; and
an epitaxially grown photo-sensor region disposed in the first epitaxial layer having a second conductivity type, wherein the epitaxially grown photo-sensor region includes an extension region that extends under a portion of the transfer transistor gate.

2. The image sensor pixel of claim 1, wherein the epitaxially grown photo-sensor region comprises a Silicon Germanium alloy.

3. The image sensor pixel of claim 1, wherein the epitaxially grown photo-sensor region extends into the first epitaxial layer and rises above a top of the first epitaxial layer.

4. The image sensor pixel of claim 3 wherein the epitaxially grown photo-sensor region forms a hemispheroidal shape above the top of the first epitaxially grown layer.

5. The image sensor pixel of claim 4, wherein the image sensor pixel comprises a frontside illuminated image sensor pixel and wherein the hemispheroidal shape is shaped into a optical lens to focus light into the epitaxially grown photo-sensor region.

6. The image sensor pixel of claim 4, wherein the image sensor pixel comprises a backside illuminated image sensor pixel and wherein the hemispheroidal shape is shaped into a reflector to reflect light back into the epitaxially grown photo-sensor region.

7. The image sensor pixel of claim 3, further comprising a pinning layer disposed over the expitaxially grown photo-sensor region, wherein the pinning layer is doped to have the first conductivity type.

8. The image sensor pixel of claim 1, wherein the epitaxially grown photo-sensor region is between approximately 200 nm and approximately 2000 nm thick.

9. The image sensor pixel of claim 1, wherein the extension region of the epitaxially grown photo-sensor region extends approximately between 40 nm and 400 nm under the transfer transistor gate.

10. The image sensor pixel of claim 1 wherein the second conductivity type comprises N type dopants having a doping concentration of approximately between 5×10¹⁴ and 5×10¹⁶ dopant atoms per cubic centimeter.

11. A method of fabricating a complementary metal-oxide-semiconductor (“CMOS”) image sensor pixel, the method comprising:
fabricating frontside components including a transfer transistor gate on a front side of the CMOS image sensor pixel, wherein the transfer transistor gate is formed over an epitaxial layer having a first conductivity type;
forming a recess in the epitaxial layer, wherein the recess extends under a portion of the transfer transistor gate; and
epitaxially growing a photo-sensor region within the recess including under the portion of the transfer transistor gate, wherein the photo-sensor region has a second conductivity type different from the first conductivity type.

12. The method of claim 11, wherein forming the recess in the epitaxial layer comprises:
forming an etch mask over the transfer transistor gate and a top surface of the epitaxial layer; and
etching the epitaxial layer to form the recess within the epitaxial layer.

13. The method of claim 12, wherein epitaxially growing the photo-sensor region within the recess comprises:
epitaxially growing the photo-sensor region to fill the recess including the under the portion of the transfer gate; and
epitaxially growing the photo-sensor region to form a raised portion that rises above the top surface of the epitaxial layer.

14. The method of claim 13, wherein the raised portion comprises a hemispheroidal shape.

15. The method of claim 14, wherein the CMOS image sensor pixel comprises a frontside illuminated image sensor pixel and wherein the hemispheroidal shape is shaped into an optical lens to focus light into the photo-sensor region.

16. The image sensor pixel of claim 14, wherein the CMOS image sensor pixel comprises a backside illuminated image sensor pixel and wherein the hemispheroidal shape is shaped into a reflector to reflect light back into the photo-sensor region.

17. The method of claim 11, wherein the epitaxially grown photo-sensor region comprises Silicon Germanium alloy.

18. The method of claim 11, further comprising:
doping a top layer of the photo-sensor region to have the first conductivity type.

19. The method of claim 11, wherein:
the photo-sensor region is between approximately 200 nm and approximately 2000 nm thick, and
the photo-sensor region extends approximately between 40 nm and 400 nm under the transfer transistor gate

20. An image sensor comprising:
a complementary metal-oxide-semiconductor (“CMOS”) array of image sensor pixels disposed on a substrate doped to have a first conductivity type, wherein each of the image sensor pixels includes:
an epitaxial layer disposed over a substrate and doped to have a first conductivity type;
a transfer transistor gate formed on the epitaxial layer; and
an epitaxially grown photo-sensor region disposed in the epitaxial layer having a second conductivity type, wherein the epitaxially grown photo-sensor region includes an extension region that extends under a portion of the transfer transistor gate; and
readout circuitry coupled to the CMOS array to readout image data from each of the image sensor pixels.

21. The image sensor of claim 20, wherein the epitaxially grown photo-sensor region comprises a Silicon Germanium alloy.

22. The image sensor of claim 21, wherein the epitaxially grown photo-sensor region extends into the epitaxial layer and rises above a top of the epitaxial layer and wherein the epitaxially grown photo-sensor region forms a hemispheroidal shape above the top of the epitaxially grown layer.
